(19) United States
(12) Patent Application Publication
(10) Pub. No.: US 2016/0044806 A1
(43) Pub. Date: Feb. 11, 2016

(54) DISPLAY APPARATUS

(71) Applicant: SAMSUNG ELECTRONICS CO., LTD., Suwon-si (KR)

(72) Inventors: Jae Hoo PARK, Suwon-si (KR); Jun Pil OH, Suwon-si (KR); Gyu Sung DO, Seoul (KR)

(73) Assignee: SAMSUNG ELECTRONICS CO., LTD., Suwon-si (KR)

(21) Appl. No.: 14/723,661

(22) Filed: May 28, 2015

(30) Foreign Application Priority Data
Aug. 5, 2014 (KR) 10-2014-0100256

(51) Int. Cl. H05K 5/02; H05K 5/00

(52) U.S. Cl. CPC H05K 5/0217; H05K 5/0086; H05K 5/0017

(57) ABSTRACT

A display apparatus configured to deform a display module in one of a flat state and a curved state is provided. The display apparatus includes a display module that is deformable and is configured to display an image, and a deformation apparatus configured to maintain the display module in one of a flat state and a curved state, wherein the deformation apparatus includes a handle unit configured to be moved by manipulation of a user, and a rotary plate configured to be rotated by movement of the handle unit and deform a curvature of the display module.

### CROSS-REFERENCE TO RELATED APPLICATION

This application claims priority from Korean Patent Application No. 10-2014-0100256, filed on Aug. 5, 2014, in the Korean Intellectual Property Office, the disclosure of which is incorporated herein by reference.

### BACKGROUND

1. Field

Apparatuses and methods consistent with exemplary embodiments relate to a display apparatus, and more particularly, to a display apparatus including a deformable display module.

2. Description of the Related Art

In general, a display apparatus includes a display module on which an image may be displayed. For example, the display apparatus may be a television or a monitor. The display apparatus that has a display module may include an organic light emitting diode panel that may be used as the display apparatus.

Since the organic light emitting diode panel may be formed of a material that is bendable, a display apparatus in which the display panel is fixedly installed may be in a curved state. In addition, a user may partially feel a three-dimensional effect that is similar to a three-dimensional image through which a two-dimensional image has been proposed.

However, a user may prefer a flat display module over a curved display module. For example, while the curved display module may improve a sense of immersion of a user under a viewing condition by one person, the curved display module may cause an inconvenience to a plurality of users under a viewing condition due to a limitation of a viewing angle.

In addition, because the flat display panel in the related art can transmit a more accurate image than that of the curved display panel, the flat display panel may be more advantageous than the curved display panel according to various contents.

### SUMMARY

According to one or more exemplary embodiments, there is provided a display apparatus including a deformation apparatus configured to deform a display module into a flat state and a curved state.

According to an aspect of another exemplary embodiment, there is provided a display apparatus including a deformation apparatus having a structure that may be directly and manually manipulated by a user, and which is capable of varying a curvature of a display module and reducing a manufacturing cost.

According to an aspect of another exemplary embodiment, there is provided a display apparatus including a display module that is deformable and configured to display an image; and a deformation apparatus configured to maintain the display module in one of a flat state and a curved state, wherein the deformation apparatus includes a handle unit configured to be moved by manipulation of a user, and a rotary plate is configured to be rotated by movement of the handle unit and deform a curvature of the display module.

The rotary plate may include a plate-shaped rotary body; a first rotary section provided at one end of the rotary body and rotatably connected to the display module; and a second rotary section provided at the other end of the rotary body and rotatably connected to the handle unit.

The handle unit may include a handle; a movable bar that is movable by the handle in leftward/rightward directions; and a rotary shaft provided at an end section of the movable bar and rotatably connected to the second rotary section.

The rotary plate may include a first rotary plate configured to deform a curvature of one side of the display module; and a second rotary plate configured to deform a curvature of the other side of the display module.

The first rotary plate and the second rotary plate may be configured to move in opposite directions.

The handle unit may include a main cylinder; a handle configured to reciprocate in the main cylinder; first and second cylinders connected to the main cylinder via a tube; and first and second piston rods configured to reciprocate in the first and second cylinders, wherein the first and second piston rods are connected to the first rotary plate and the second rotary plate, respectively.

The first cylinder and the second cylinder may be configured to move the first piston rod and the second piston rod in opposite directions.

The display module may further include an installation panel that has a rear surface at which the handle unit is installed.

The handle may be exposed to an outside of the display apparatus.

According to an aspect of another exemplary embodiment, there is provided a display apparatus including: a display module that is deformable and is configured to display an image; a case disposed at a rear of the display module; a handle that is at least partially exposed to the outside of the case; and a rotary plate configured to rotate according to a movement of the handle to deform the display module.

The handle may be configured to be manipulated by a user to move linearly.

The rotary plate may include a first rotary plate disposed at one side of the display module; and a second rotary plate disposed at the other side of the display module, wherein the first rotary plate and the second rotary plate are configured to move in opposite directions.

The handle may include a movable bar connected to the rotary plate via a shaft.

The handle may include a first handle connected to the first rotary plate; and a second handle connected to the second rotary plate, wherein the first handle and the second handle are configured to move in different directions.

According to an aspect of another exemplary embodiment, there is provided a display apparatus including: a display module that is deformable and is configured to display an image; a first rotary plate rotatably provided at a first side area of a rear of the display module; a second rotary plate rotatably provided at a second side area of the rear of the display module; and a handle unit configured to rotate the first rotary plate and the second rotary plate in opposite directions to deform a curvature of the display module.

The rotary plate may include a plate-shaped rotary body; a first rotary section provided at one end of the rotary body and rotatably connected to the display module; and a second rotary section provided at the other end of the rotary body and rotatably connected to the handle unit.

The handle unit may include a handle; a movable bar configured to be moved by the handle; and a shaft provided at an end of the movable bar and rotatably connected to the second rotary section.

The handle unit may include a main cylinder; a handle that is configured to be reciprocable in the main cylinder; first and second cylinders connected to the main cylinder via a tube; and first and second piston rods configured to be reciprocable in the first and second cylinders.

The first piston rod may be connected to the first rotary plate and the second piston rod may be connected to the second rotary plate to move in opposite directions.

The handle may be exposed to the outside of the display apparatus.

### BRIEF DESCRIPTION OF THE DRAWINGS

The above and/or other aspects will become more apparent and more readily appreciated from the following description of the exemplary embodiments, taken in conjunction with the accompanying drawings, in which:

FIG. 1 is a diagram illustrating a display apparatus according to an exemplary embodiment;

FIG. 2 is a diagram illustrating a curved state of a display module of the display apparatus according to an exemplary embodiment;

FIG. 3 is an exploded perspective view illustrating a deformation apparatus of the display apparatus according to an exemplary embodiment;

FIG. 4 is a plan view illustrating the deformation apparatus of the display apparatus according to an exemplary embodiment;

FIG. 5 is a view schematically illustrating a flat state of the display module of the deformation apparatus according to an exemplary embodiment;

FIG. 6 is a diagram illustrating a curved state of the display module of the deformation apparatus according to an exemplary embodiment;

FIG. 7 is an exploded perspective view illustrating a deformation apparatus of a display apparatus according to another exemplary embodiment;

FIG. 8 is a plan view schematically illustrating the deformation apparatus according to another exemplary embodiment;

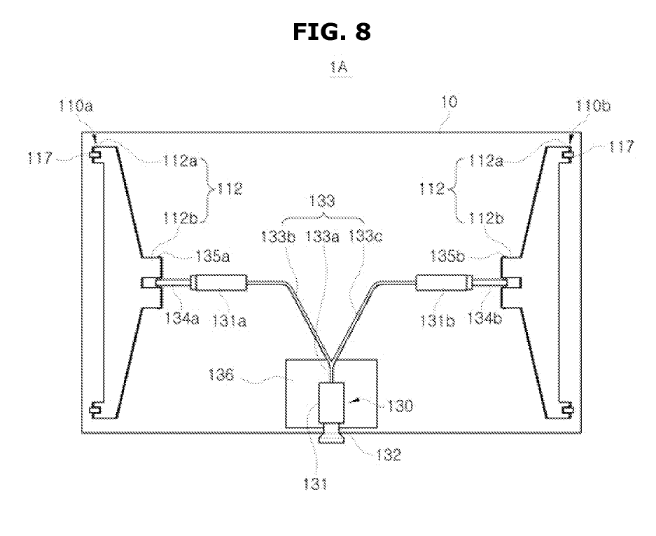

FIG. 9 is a diagram illustrating a flat state of the display module by the deformation apparatus according to another exemplary embodiment; and

FIG. 10 is a diagram illustrating a curved state of the display module by the deformation apparatus according to another exemplary embodiment.

### DETAILED DESCRIPTION

Reference will now be made in detail to the exemplary embodiments of the present invention, examples of which are illustrated in the accompanying drawings, wherein like reference numerals should be understood to refer to like elements throughout.

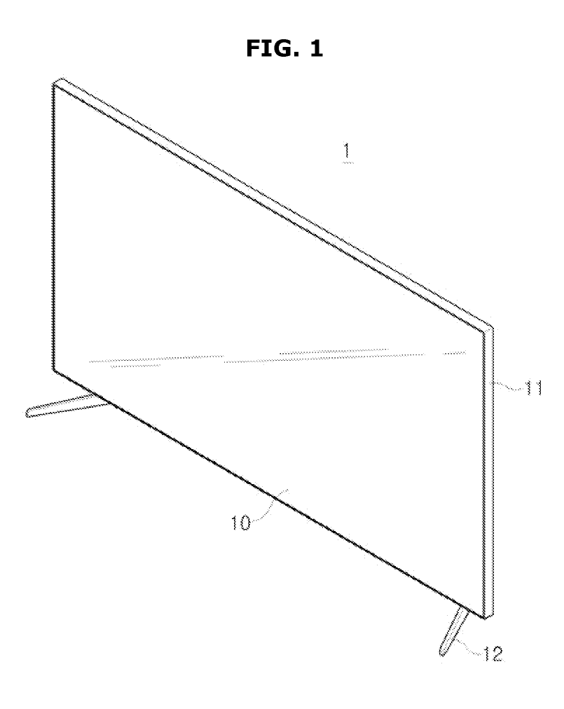

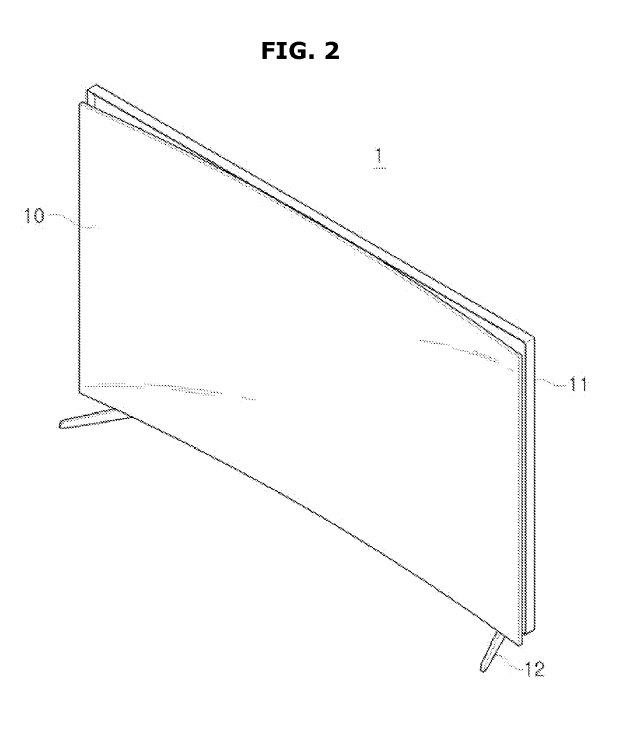

Referring to FIGS. 1 and 2, a display apparatus 1 includes a display module 10 configured to display image information, and a case 11 that is disposed outside the display module 10 and that is configured to protect the display module 10 and the electronic parts that are included therein.

The display module 10 includes a display panel that may be formed of an organic light emitting diode panel, and a base panel that has a shape corresponding to the display panel and which is configured to support a rear surface of the display panel.

The case 11 may surround a front periphery and a rear surface of the display module 10. Also, a base 12 that is supported on an installation surface of which the display apparatus 1 is installed may be provided on a lower section of the case 11. For example, the display module 10 and the base 12 may be connected to each other by a stand 13 that is vertically provided on the base 12.

The display module 10 is deformable or flexible, and both side ends thereof may protrude forward from a center thereof to form a curvature. As shown in the examples of FIGS. 1 and 2, the display module 10 may include a flat state and a curved state in which both ends protrude forward such that the display module has a certain curvature.

According to one or more exemplary embodiments, the display apparatus 1 may include a deformation apparatus 100 that is capable of deforming the display module 10 into one of the flat state and the curved state.

For example, the deformation apparatus 100 may be a manual structure that may be directly manipulated by a user.

In some examples, the display module 10 and the case 11 may be formed of a bendable material, and they may be bent into a curved shape by the deformation apparatus 100.

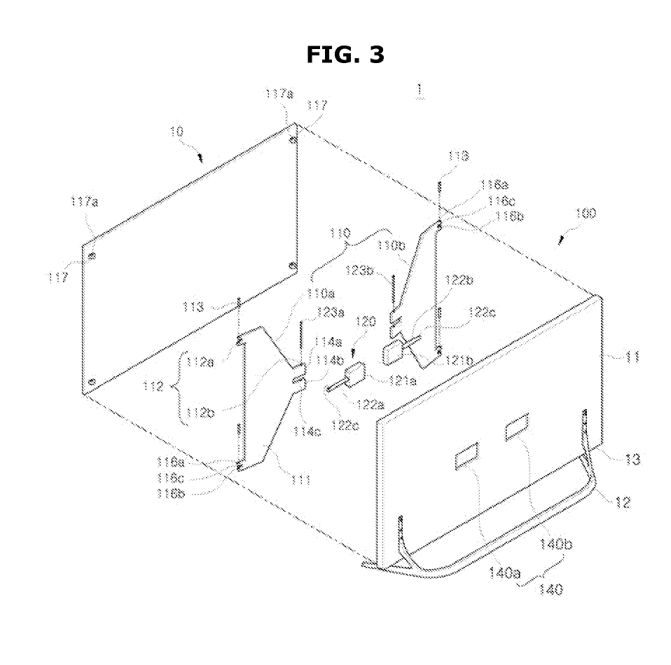

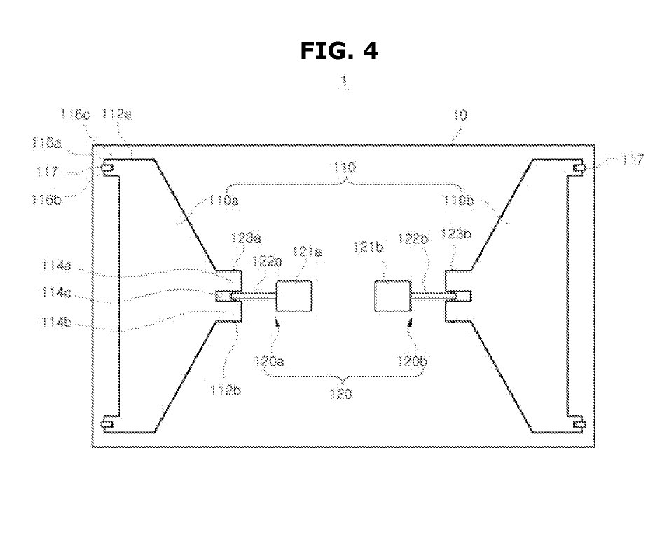

As shown in the examples of FIGS. 3 and 4, the deformation apparatus 100 may be disposed between the display module 10 and the case 11 to maintain a state in which both ends of the display module 10 are disposed at a forward side of the center in order to form a curved state that protrudes forward from a center of the display module 10.

For example, the deformation apparatus 100 may include rotary plates 110 that are provided at the rear of the display module 10, and handle units 120 that are configured to rotate the rotary plates 110.

The rotary plates 110 may include a first rotary plate 110a that is disposed at one side area (for example, the left side area) of the rear of the display module 10 and a second rotary plate 110b that is disposed at the other side area (for example, the right side area) of the rear of the display module 10.

The first rotary plate 110a and the second rotary plate 110b may be disposed such that they are symmetrical with respect to each other to move in opposite directions.

Accordingly, one side of the display module 10 may be rotated by the first rotary plate 110a to vary a curvature, and the other side of the display module 10 may be rotated by the second rotary plate 110b to vary a curvature.

In this example, the first rotary plate 110a and the second rotary plate 110b may be moved by the handle units 120. For example, the handle units 120 may include a first handle unit 120a that is connected to the first rotary plate 110a and a second handle unit 120b that is connected to the second rotary plate 110b.

Accordingly, the first rotary plate 110a may be rotated by the first handle unit 120a connected to the first rotary plate 110a, and the second rotary plate 110b may be rotated by the second handle unit 120b connected to the second rotary plate 110b.

For example, because the first rotary plate 110a and the second rotary plate 110b have the same shape and configuration, the plates may perform the same operation. For example, the first rotary plate 110a and the second rotary plate 110b may be disposed in opposite directions and be rotated in opposite directions.

Referring again to FIGS. 1 and 2, a curvature of one side of the display module 10 may be deformed by a movement of the first rotary plate 110a, a curvature of the other side of the display module 10 may be deformed by a movement of the second rotary plate 110b, and curvatures of both sides of the display module 10 may be deformed by a movement of both the first rotary plate 110a and the second rotary plate 110b.

Accordingly, a user may manually manipulate the handle unit 120 to variously manipulate a curvature state of the display module 10.

Furthermore, in this example the rotary plates 110 may include plate-shaped rotary bodies 111.

The rotary body 111 includes a rotary section 112 that may be configured to rotate the display module 10. For example, the rotary section 112 may include first rotary sections 112a provided at one side of the rotary body 111 and that are connected to the display module 10, and second rotary sections 112b that are provided at the other side of the rotary body 111 and that are connected to the handle unit 120.

Here, the first rotary sections 112a are formed at upper and lower ends of one side of the rotary body 111 such that they may be connected to an upper end section and a lower end section of the display module 10. Also, the second rotary sections 112b may be connected to the handle unit 120 and may be formed at a center of the other side that is opposite to the first rotary section 112a.

As the second rotary section 112b is disposed at a center of the rotary body 111, the first rotary sections 112a may be rotated according to a movement of the second rotary section 112b which may transmit a uniform force to both of the upper and lower sections of the display module 10.

Accordingly, the force of the handle unit 120 may be applied to the second rotary section 112b and may be uniformly transmitted to the upper and lower sections of the display module 10 through the first rotary sections 112a, and thus, the curvature of the display module 10 may be uniformly deformed.

Each of the first rotary sections 112a may be symmetrically formed at upper and lower ends on one side of the rotary body 111 that includes a first rotary protrusion 116a protruding from an end section of the rotary body 111, a second rotary protrusion 116b that is spaced apart from the first rotary protrusion 116a, and a rotary slot 116c that is formed in a space between the first rotary protrusion 116a and the second rotary protrusion 116b.

A first rotary hole 116d to which a rotary shaft 113 is coupled and which may be formed to pass through the first rotary protrusion 116a and the second rotary protrusion 116b.

The display module 10 also includes rotary fixing sections 117 to which the first rotary sections 112a of the rotary body 111 are rotatably coupled. For example, the rotary fixing section 117 may have a rotary hole 117a through which the rotary shaft 113 passes.

Accordingly, the rotary fixing section 117 of the display module 10 may be inserted into the rotary slot 116c and be formed between the first rotary protrusion 116a and the second rotary protrusion 116b of the first rotary section 112a of the rotary body 111. Also, the rotary shaft 113 passes through the first rotary hole 116d and the rotary hole 117a such that the rotary body 111 and the display module 10 are rotatably coupled.

The rotary fixing sections 117 are formed at upper and lower end sections of the display module 10 in order to correspond to the first rotary sections 112a. For example, the second rotary section 112b may be rotatably coupled to the handle unit 120.

The second rotary sections 112b are formed at a center of the other ends of the rotary bodies 111. The second rotary sections 112b include first hinge protrusions 114a that protrude from centers of the other ends of the rotary bodies 111, second hinge protrusions 114b that are spaced apart from lower sides of the first hinge protrusions 114a, and hinge slots 114c that are formed in spaces between the first hinge protrusions 114a and the second hinge protrusions 114b.

In this example, holes 114d to which hinge shafts 135a are coupled may be formed at the first hinge protrusions 114a and the second hinge protrusions 114b as shown in the example of FIG. 4.

The hinge shaft 135a may connect the handle unit 120 and the rotary plate 110, an example of which is described below.

The handle units 120 include handles 121a and 121b, movable bars or rods 122a and 122b connected to the handles 121a and 121b may be movable, and hinge shafts 123a and 123b connected to an end section of the movable bars 122a and 122b may be movable with respect to the second rotary sections 112b.

The handle 121 is exposed to an outside of the case 11 of the display apparatus 1 and is capable of being manually moved by a user.

Handle installation holes 140 through which the handles 121 are exposed may be movable by the user and may be formed in a rear surface of the case 11.

The handles 121 include a first handle 121a that is connected to the first rotary plate 110a, and a second handle 121b that is connected to the second rotary plate 110b.

In this example, the handle installation holes 140 may be formed in the case 11 and may include a first handle installation hole 140a through which the first handle 121a is installed, and a second handle installation hole 140b through which the second handle 121b is installed.

The first handle installation hole 140a and the second handle installation hole 140b may be formed such that they can move in a lateral direction of the display module 10.

In this example, while the handle installation holes 140 of the exemplary embodiment are shown as being respectively formed for each of the handles to be installed at the rear surface of the case 11 to move one side and the other side of the display module 10, the exemplary embodiments are not limited thereto. For example, the handle installation holes through which the handles are installed may be formed as one slot through which both of the handles are installed.

Hinge through-holes 122c through which the hinge shafts 135a and 135b pass are formed in an end of the movable bars 122a and 122b may be connected to the handles 121a and 122b in a horizontal direction.

In this example, when end sections of the movable bars 122a and 122b are inserted into the hinge slots 114c of the second rotary sections 112b of the rotary plates 110, the hinge shafts 135a and 135b may pass through the hinge holes 114d that are formed in the first hinge protrusion 114a and the second hinge protrusion 114b and the hinge through-holes 122c of the movable bars 122a and 122b may be coupled thereto.

Accordingly, the movable bars 122a and 122b connected to the handles 121a and 121b may be moved toward the rotary plates 110a and 110b using the handles 121a and 121b, and side ends of the display module 10 are rotated and moved forward to form a curved state while rotating about the first rotary sections 112a of the rotary plates 110a and 110b.

While the handle unit 120 is shown as an example of being installed at the rear surface of the display module 10, the exemplary embodiments are not limited thereto. For example, a plate-shaped bracket that is configured to install the handle unit may be installed at a rear surface of the display module 10.

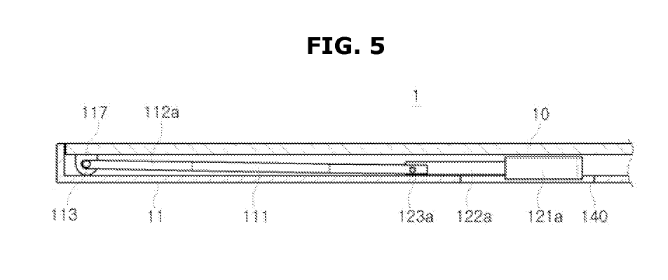

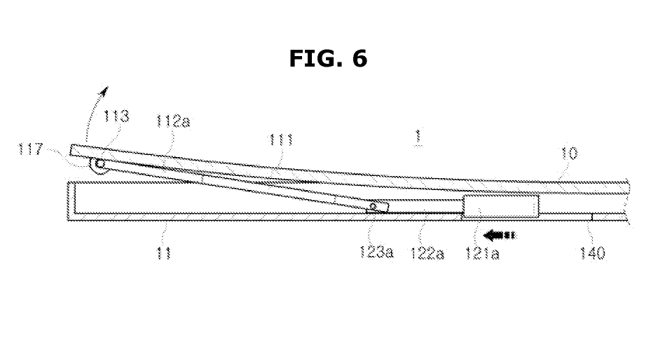

Also, in FIGS. 5 and 6, a deformation operation of the display module 10 of the display apparatus 1 is described. In these examples, as shown in FIG. 5, the display module 10 of the display apparatus 1 may be used in a flat state. Here, when the user moves the first handle 121a of the deformation apparatus 100, the movable bar 122a connected to the first handle 121a is also moved.

The second rotary section 112b of the first rotary plate 110a that is connected to the movable bar 122a is rotated about the hinge shaft 123a while the movable bar 122a moves. In this example, the first rotary section 112a of the first rotary plate 110a may be rotatably connected to the rotary fixing section 117 of the display module 10. Accordingly, one end of the display module 10 may be disposed in front of the first rotary plate 110a and may be rotated to move forward when the first rotary plate 110a is rotated.

Accordingly, a curvature of one end of the display module 10 can be deformed to maintain the curved state.

On the other hand, when the user restores the first handle 121 to its original position, the first rotary plate 110a is moved to the original position and the display module 10 becomes the flat state.

According to various examples, the operations of the second rotary plate 110b and the second handle 121b having the same configuration as described above may be substantially expected from the above-mentioned description, accordingly, detailed description thereof may be omitted.

For example, the second handle 121b may include the movable bar 122b that is connected to the second handle 121b and that is movable, and the hinge shaft 123b that is provided at the end section of the movable bar 122b to be rotatably connected to the second rotary section 112b of the second rotary plate 110b.

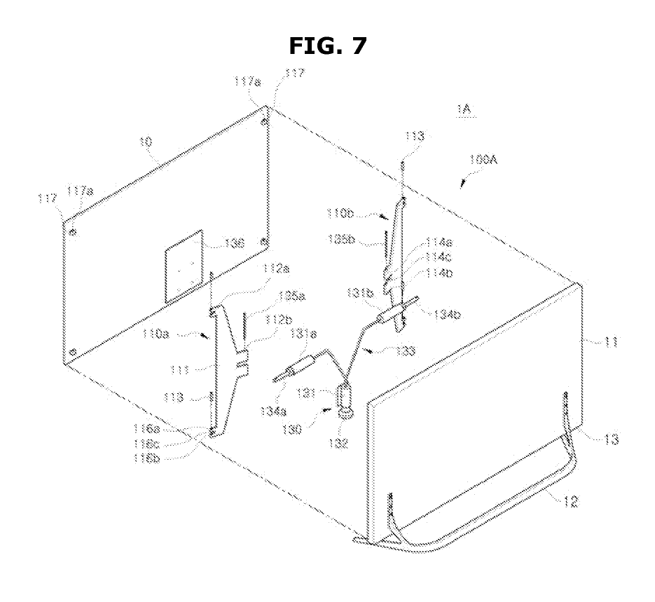

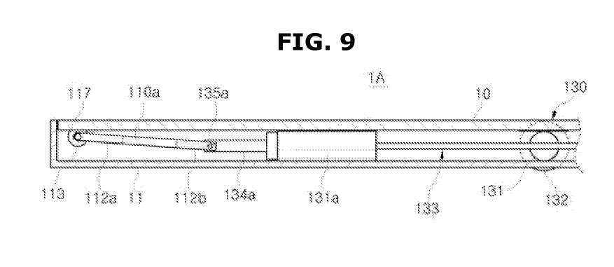

Referring to FIGS. 7 and 9, a deformation apparatus 100A according to another embodiment includes rotary plates 110, and a handle unit 130 which is configured to rotate the rotary plates 110.

For example, rotary plates 110 may be disposed at one side and the other side of the display module 10, and may include the first rotary plate 110a disposed at one side of the display module 10 and the second rotary plate 110b disposed at the other side of the display module 10. Also, the rotary plate 110 may include the plate-shaped rotary body 111.

In this example, the rotary body 111 includes the rotary section 112 that is configured to rotate the display module 10. Also, the rotary section 112 includes the first rotary sections 112a provided at one end of the rotary body 111 and that are connected to the display module 10, and the second rotary section 112b that is provided at the other end of the rotary body 111 and that is connected to the handle unit 130.

For example, the first rotary sections 112a are formed at upper and lower end sections of the rotary body 111 and that are connected to the upper end section and the lower end section of the display module 10. Also, the second rotary section 112b is provided at a center of another side of the rotary body that is connected to the handle unit 130.

As the second rotary section 112b is disposed at a center of the rotary body 111, the first rotary sections 112a of the rotary body 111 rotated according to a movement of the second rotary section 112b can transmit a uniform force to the upper and lower sections of a side of the display module 10.

Accordingly, because the force of the handle unit 130 applied to the second rotary section 112b may be uniformly transmitted to the upper and lower sections of the display module 10 through the first rotary sections 112a, the curvature of the display module 10 may be uniformly deformed.

As an example, the first rotary sections 112a symmetrically formed at upper and lower end sections of a side of the rotary body 111 include the first rotary protrusions 116a protruding from an end of the rotary body 111, the second rotary protrusions 116b spaced apart from the first rotary protrusions 116a, and the rotary slots 116c formed in spaces between the first rotary protrusions 116a and the second rotary protrusions 116b.

The first rotary hole 116d through which the rotary shaft 113 is coupled is formed to pass through the first rotary protrusion 116a and the second rotary protrusion 116b.

Also, the display module 10 may include the rotary fixing sections 117 to which the first rotary protrusions 116a are rotatably coupled. The rotary fixing sections 117 have the rotary hole 117a through which the rotary shaft 113 passes.

Accordingly, the rotary fixing section 117 of the display module 10 may be inserted into the rotary slot 116c that is formed between the first rotary protrusion 116a of the second rotary protrusion 116b of the first rotary section 112a of the rotary body 111. Also, the rotary shaft 113 passes through the first rotary hole 116d and the rotary hole 117a such that the rotary body 111 and the display module 10 are rotatably coupled.

In these examples, the rotary fixing sections 117 are formed at upper and lower end sections of the display module 10 to correspond to the first rotary sections 112a. Accordingly, the second rotary section 112b is rotatably coupled to the handle unit 130.

In this example, the second rotary section 112b is formed at a center of the other end of the rotary body 111. The second rotary section 112b includes the first hinge protrusion 114a that protrudes from a center of the other end of the rotary body 111, the second hinge protrusion 114b is spaced apart from a lower side of the first hinge protrusion 114a, and the hinge slot 114c is formed in a space that is between the first hinge protrusion 114a and the second hinge protrusion 114b.

The hinge holes 114d through which the hinge shaft 135a is coupled may be formed at the first hinge protrusion 114a and the second hinge protrusion 114b, accordingly.

For example, a piston rod 134 (an example of which is described below) is inserted into the hinge slot 114c between the first hinge protrusion 114a and the second hinge protrusion 114b, and the hinge shaft 135a passes through the hinge hole 114d and a hinge shaft hole 134c formed at an end of the piston rod 134 in order to connect the handle unit 130 and the rotary plate 110.

The handle unit 130 also includes a main cylinder 131, a handle 132 disposed inside the main cylinder 131, a first cylinder 131a and a second cylinder 131b that is connected to the main cylinder 131 via a tube 133. The handle unit 130 also includes a first piston rod 134a and a second piston rod 134b that reciprocate in the first cylinder 131a and the second cylinder 131b, respectively.

The main cylinder 131 may be disposed in a center lower section of the display module 10. The handle 132 reciprocally provided in the main cylinder 131 may be manually operated by a user.

In this example, the first cylinder 131a and the second cylinder 131b are connected to the main cylinder 131 via the tube 133.

The tube 133 may further include a first tube 133a that is connected to an end of the main cylinder 131, a second tube 133b that branches off from the first tube 133a in order to be connected to the first cylinder 131a, and a third tube 133c that branches off from the first tube 133a to be connected to the second cylinder 131b.

Accordingly, if pressure forms on the main cylinder 131 by pressurization of the handle 132, the pressure may be transmitted to the first cylinder 131a and the second cylinder 131b through the tube 133. As a result, the first piston rod 134a and the second piston rod 134b connected to the first cylinder 131a and the second cylinder 131b may be moved.

As an example, the first piston rod 134a and the second piston rod 134b move in different directions.

In this example, the first piston rod 134a and the second piston rod 134b are connected to different rotary plates 110. That is, the first piston rod 134a is connected to the first rotary plate 110a, and the second piston rod 134b is connected to the second rotary plate 110b.

Also, the first piston rod 134a and the second piston rod 134b are coupled to the second rotary section 112b and the hinge shaft 135a of the first and second rotary plates 110a and 110b. For example, the hinge shaft hole 134c may be formed at an end section of the first piston rod 134a and an end section of the second piston rod 134b through which the hinge shafts 135a may pass.

The first rotary plate 110a and the second rotary plate 110b are disposed such that they are symmetrical with respect to each other and are provided to move in opposite directions.

Also, the first cylinder 131a and the second cylinder 131b are disposed at a center of the display module 10, for example, a center of the rotary body 111. In this example, the first cylinder 131a and the second cylinder 131b, and the first piston rod 134a and the second piston rod 134b connected to the first cylinder 131a and the second cylinder 131b transmit a high pressure air to the second rotary sections 112b that is provided at centers of the rotary plates 110, and the second rotary section 112b can uniformly transmit the high pressure air to the first rotary sections 112a disposed at the upper and lower sections of the display module 10.

For example, one cylinder may receive the high pressure air that is compressed by the main cylinder and the handle that is transmitted may be formed at each display module. However, the exemplary embodiments are not limited thereto. For example, the number of cylinders may be variously changed according to a size and a shape of the display module.

Also, while the exemplary embodiments include the handle disposed at a lower end and a center of the display apparatus, the exemplary embodiments are not limited thereto. For example, the handle may be disposed at a rear surface or a side surface of the case.

Also, an installation panel 136 may install the handle unit 130 and may be provided at the rear surface of the display module 10.

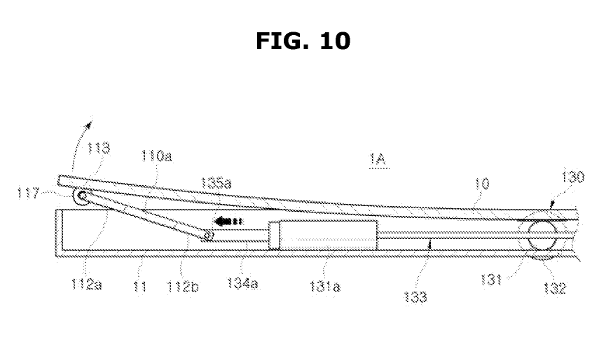

As shown in the examples of FIGS. 9 and 10, state deformation of the display module 10 of a display apparatus 1A by the handle unit 130 of the deformation apparatus 100A is described.

For example, as shown in FIG. 9, the display module 10 of the display apparatus 1 A may be used in a flat state.

When a user presses and linearly moves the handle 132 of the deformation apparatus 100A, the handle 132 may compress the air in the main cylinder 131. In this example, the compressed air may move to the first cylinder 131a and the second cylinder 131b through the tubes 133, 133a, and 133b.

In this example, the first piston rod 134a of the first cylinder 131a and the second piston rod 134b of the second cylinder 131b may be moved in opposite directions.

Also, the first rotary plate 110a and the second rotary plate 110b may be rotated by the second rotary sections 112b that are connected to the first piston rod 134a and the second piston rod 134b, respectively.

Accordingly, because the first rotary sections 112a of the first and second rotary plates 110 are connected to the rotary fixing sections 117 of the display module 10, the curvature of the display module 10 is varied when the first and second rotary plate 110 are rotated.

Both end sections of the display module 10 may move forward from the center to form a curved shape.

In addition, when a user pulls to return the handle 132 to the original position, the display module 10 may transition to a flat state.

As is apparent from the above description, according to the exemplary embodiments, the display module of the display apparatus may selectively use one of the flat state and the curved state.

For example, because the deformation apparatus that may deform the display module may be manually performed, the manufacturing cost may be reduced.

Although a few exemplary embodiments of the present invention have been shown and described, it should be appreciated by those skilled in the art that various changes may be made to these exemplary embodiments without departing from the principles and spirit of the inventive concept, the scope of which is defined in the following claims and their equivalents.

What is claimed is:

1. A display apparatus comprising:
a display module that is deformable and is configured to display an image; and
a deformation apparatus configured to maintain the display module in one of a flat state and a curved state, the deformation apparatus comprising a handle unit configured to be moved by manipulation of a user, and a rotary plate configured to be rotated by movement of the handle unit and change a curvature of the display module.

2. The display apparatus according to claim 1, wherein the rotary plate comprises:
a plate-shaped rotary body;
a first rotary section provided at a first end of the rotary body and rotatably connected to the display module; and
a second rotary section provided at a second end of the rotary body and rotatably connected to the handle unit.

3. The display apparatus according to claim 2, wherein the handle unit comprises:
a handle;
a movable bar configured to be moved by the handle in a leftward direction and a rightward direction; and
a rotary shaft provided at an end section of the movable bar and rotatably connected to the second rotary section.

4. The display apparatus according to claim 3, wherein the rotary plate comprises:
a first rotary plate configured to deform a curvature of a first side of the display module; and
a second rotary plate configured to deform a curvature of a second side of the display module.

5. The display apparatus according to claim 4, wherein the first rotary plate and the second rotary plate are configured to move in opposite directions.

6. The display apparatus according to claim 1, wherein the handle unit comprises:
a main cylinder;
a handle configured to reciprocate within the main cylinder;
first and second cylinders connected to the main cylinder via a tube; and
first and second piston rods configured to reciprocate within the first and second cylinders,
wherein the first and second piston rods are connected to a first rotary plate and a second rotary plate, respectively.

7. The display apparatus according to claim 6, wherein the first cylinder and the second cylinder are configured to move the first piston rod and the second piston rod in opposite directions.

8. The display apparatus according to claim 6, wherein the display module further comprises an installation panel having a rear surface at which the handle unit is installed.

9. The display apparatus according to claim 6, wherein the handle is at least partially exposed to an outside of the display apparatus.

10. A display apparatus comprising:
a display module that is deformable and is configured to display an image;
a case disposed at a rear of the display module;
a handle that is at least partially exposed to an outside of the case; and
a rotary plate configured to rotate according to a movement of the handle to deform the display module.

11. The display apparatus according to claim 10, wherein the handle is configured to be gripped by a user to move linearly.

12. The display apparatus according to claim 10, wherein the rotary plate comprises:
a first rotary plate disposed at a first side area of a rear of the display module; and
a second rotary plate disposed at a second side area of a rear of the display module,
wherein the first rotary plate and the second rotary plate are configured to move in opposite directions.

13. The display apparatus according to claim 12, wherein the handle comprises a movable bar connected to the rotary plate via a shaft.

14. The display apparatus according to claim 13, wherein the handle comprises:
a first handle connected to the first rotary plate; and
a second handle connected to the second rotary plate,
wherein the first handle and the second handle are configured to move in different directions.

15. A display apparatus comprising:
a display module that is deformable and is configured to display an image;
a first rotary plate rotatably provided at a first side area of to a rear of the display module;
a second rotary plate rotatably provided at a second side area of the rear of the display module; and
a handle unit configured to rotate the first rotary plate and the second rotary plate in opposite directions to deform a curvature of the display module.

16. The display apparatus according to claim 15, wherein the rotary plate comprises:
a plate-shaped rotary body;
a first rotary section provided at one end of the rotary body and rotatably connected to the display module; and
a second rotary section provided at the other end of the rotary body and rotatably connected to the handle unit.

17. The display apparatus according to claim 15, wherein the handle unit comprises:
a handle;
a movable bar configured to be moved by the handle; and
a shaft provided at an end of the movable bar and rotatably connected to the second rotary section.

18. The display apparatus according to claim 15, wherein the handle unit comprises:
a main cylinder;
a handle configured to reciprocate within the main cylinder;
first and second cylinders connected to the main cylinder via a tube; and
first and second piston rods configured to reciprocate in the first and second cylinders.

19. The display apparatus according to claim 18, wherein the first piston rod is connected to the first rotary plate and the second piston rod is connected to the second rotary plate to move in opposite directions.

20. The display apparatus according to claim 18, wherein the handle is exposed to an outside of the display apparatus.

21. A display apparatus comprising:
a display module that is deformable;
a case provided at a rear surface of the display module; and
at least one plate that is provided between the display module and the case and is rotatably coupled to a rear surface of the display module, the at least one plate being movable to change a curvature of the display module.

22. The display apparatus of claim 21, further comprising a handle configured to be manipulated by a user to rotate the plate.

23. The display apparatus of claim 22, further comprising a rod connected between the handle and the plate, the rod being configured to move laterally by manipulation of the handle to rotate the plate.

24. The display apparatus of claim 23, wherein the plate comprises:
a plate-shaped rotary body;
a first rotary section provided at a first end of the rotary body and rotatably coupled to the rear surface the display module; and
a second rotary section provided at a second end of the rotary body and rotatably coupled to the rod.

25. The display apparatus of claim 21, wherein the at least one plate comprises:
a first plate rotatably coupled to a first side area of the rear surface of the display module; and
a second plate rotatably coupled to a second side area of the rear surface of the display module,
wherein the first plate and the second plate are configured to rotate in opposite directions.
